(19) United States
(12) Patent Application Publication
(10) Pub. No.: US 2009/0311870 A1
(43) Pub. Date: Dec. 17, 2009

(54) PLASMA ETCHING METHOD AND PLASMA ETCHING APPARATUS

(75) Inventor: Masaru SASAKI, Tokyo (JP)

Correspondence Address: PEARNE & GORDON LLP, 1801 EAST 9TH STREET, SUITE 1200, CLEVELAND, OH, 44114-3108, US

(73) Assignee: Tokyo Electron Limited, Tokyo (JP)

(21) Appl. No.: 12/482,698

(22) Filed: Jun. 11, 2009

(30) Foreign Application Priority Data
Jun. 11, 2008 (JP) 2008-152816

(51) Int. Cl. H01L 21/302; H05H 1/30

(52) U.S. Cl. 438/719; 156/345.41; 438/726; 257/E21.218

(57) ABSTRACT

Provided is a plasma etching method capable of controlling an etching shape readily and properly during a plasma etching process. The plasma etching method includes: holding a semiconductor substrate W on a holding table 14 installed in a processing chamber 12; generating a microwave for plasma ignition; generating plasma in the processing chamber 12 by setting a gap between the dielectric plate 16 and the holding table 14 to be equal to or greater than about 100 mm and setting a pressure inside the processing chamber 12 to be equal to or higher than about 50 mTorr, and introducing the microwave into the processing chamber 12 via the dielectric plate 16; and performing a plasma etching process on the semiconductor substrate W by the plasma generated by supplying a reactant gas for plasma etching process into the processing chamber 12.

### FIELD OF THE INVENTION

The present disclosure relates to a plasma etching method and a plasma etching apparatus; and, more particularly, to a plasma etching method and a plasma etching apparatus for use in a semiconductor device manufacturing process.

### BACKGROUND OF THE INVENTION

A semiconductor device such as a LSI (Large Scale Integrated circuit) or the like is manufactured by performing a plurality of processes such as etching, CVD (Chemical Vapor Deposition), sputtering, and the like on a semiconductor substrate. As for the etching, the CVD and the sputtering processes, processing methods using plasma as an energy source, i.e., plasma etching, plasma CVD, plasma sputtering or the like may be employed.

With a recent trend of multilayered wiring or miniaturization of the LSI, the above-mentioned plasma process is effectively used in respective processes for manufacturing a semiconductor device. For example, parallel plate type plasma, ICP (Inductively Coupled Plasma), ECR (Electron Cyclotron Resonance) plasma or the like generated by various types of apparatuses is used for the plasma processes of manufacturing a semiconductor device such as a MOS transistor.

A plasma processing apparatus for performing a plasma etching process using ICP is disclosed in Japanese Patent Laid-open Publication Nos. 2002-134472 (Patent Document 1) and H10-261629 (Patent Document 2).
Patent Document 1: Japanese Patent Laid-open Publication No. 2002-134472
Patent Document 2: Japanese Patent Laid-open Publication No. H10-261629

### BRIEF SUMMARY OF THE INVENTION

In Patent Document 1, etching of a silicon nitride film is performed in an etching apparatus using ICP, wherein a gap between a coil for generating plasma and a substrate to be processed is set to be in a range of about 80 mm to 1000 mm, and a pressure of a reactant gas is set to be in a range of about 2.7 Pa (20 mTorr) to 66.7 Pa (500 mTorr). As a result, a plasma etching process having a high selectivity to a silicon nitride film as compared to a silicon oxide film is performed.

Further, in accordance with Patent Document 2, a plasma etching process is carried out by using an electromagnetically coupled plasma generator while flowing at least one kind of fluorine-containing etching gas; maintaining a silicon-containing surface at a temperature of about 200° C.; and setting a pressure in a range of about 1 to 200 mTorr.

However, in the plasma etching processes as disclosed in Patent Documents 1 and 2, plasma is generated by an ICP source. Since the plasma generated by the ICP source is likely to have high-energy electrons therein, an electron temperature increases. The plasma having such a high electron temperature may re-dissociate an etching reaction product generated in the etching process, e.g., SiBr. Then, Br generated in the vicinity above a semiconductor substrate by the re-dissociation of SiBr may serve as an etchant, contributing to the etching again, or may cause an unintended deposition (deposit). As a result, a micro-loading effect is shown, that is, an etching rate is decreased as a hole diameter or a groove size is reduced, or there may be caused a difference in sparseness and denseness in etching shape, or a reduction in the etching selectivity. Resultantly, it becomes difficult to control the etching shapes during the plasma etching process.

Especially, in a plasma etching process of a polysilicon layer, a reactant gas having a low molecular weight such as HBr, Cl₂, CF₄ or the like is used. In such a case, the re-dissociation of an etching reaction product in the vicinity above the semiconductor substrate has a great influence upon the etching process, whereas the dissociation of the reactant gas has a small influence upon the etching process. The etching reaction product has a low vapor pressure, and it flows along the semiconductor substrate thereabove. Thus, as the amount of Br or the like generated by the re-dissociation in the vicinity of the semiconductor substrate increases, the above-stated tendency becomes more conspicuous.

In a conventional plasma etching apparatus using ICP, an etching process needs to be performed under an extremely low pressure condition of, e.g., about tens of mTorr or several mTorr to suppress the above-stated micro-loading effect, the difference in the sparseness and denseness in etching shape and the reduction of etching selectivity. Particularly, in the plasma etching apparatus using ICP, the etching process needs to be performed at a pressure ranging from about 20 to 30 mTorr. Further, such a tendency is also found in the above-mentioned ECR plasma or parallel plate type plasma. In the ECR plasma, for example, the etching process needs to be performed at a lower pressure of about 2 to 3 mTorr. However, a processing condition requiring such a low pressure range is not desirable in consideration of equipments or the like.

In view of the foregoing, the present disclosure provides a plasma etching method capable of controlling an etching shape readily and properly in a plasma etching process.

Further, the present disclosure also provides a plasma etching apparatus capable of controlling an etching shape readily and properly in a plasma etching process.

In accordance with an aspect of the present disclosure, there is provided a plasma etching method for performing a plasma etching process on a target substrate to be processed. The plasma etching method includes: holding the target substrate on a holding table installed in a processing chamber; generating a microwave for plasma excitation; generating plasma in the processing chamber by setting a gap between the holding table and a dielectric plate, which is disposed at a position facing the holding table to generate the plasma in the processing chamber by introducing the microwave into the processing chamber, to be equal to or greater than about 100 mm and setting a pressure inside the processing chamber to be equal to or higher than about 50 mTorr, and introducing the microwave into the processing chamber via the dielectric plate; and performing a plasma etching process on the target substrate by the plasma generated by supplying a reactant gas for plasma etching process into the processing chamber.

In accordance with this plasma etching method, since plasma is generated by using the microwave as a plasma source, a possibility of presence of high-energy electrons is low and an electron temperature is low. Further, as a distance from an area directly under the dielectric plate, i.e., a plasma generation area is increased, plasma becomes uniform and the electron density of plasma is decreased and the amount of plasma having a high electron temperature is reduced. Furthermore, as the pressure inside the processing chamber is increased to above a preset pressure, the electron density of plasma is decreased and the amount of plasma having a high electron temperature is reduced. Here, by setting the gap between the holding table and the dielectric plate to be equal to or greater than about 100 mm and the pressure inside the processing chamber to be equal to or higher than about 50 mTorr, the plasma etching process can be performed under a condition that plasma necessary for the plasma etching process is in a uniform state and the amount of plasma having a high electron temperature is reduced. Therefore, re-dissociation of a reaction product generated during the etching process can be suppressed, so that a micro-loading effect or a difference in sparseness and denseness of etching shapes can be suppressed and a reduction of etching selectivity can be prevented. Furthermore, under such a relatively high pressure condition, the plasma etching process can be performed readily in consideration of equipments. Thus, a control of etching shapes can be readily and properly carried out during the plasma etching process. Further, in case of using plasma generated by the microwave, even if the above-mentioned distance, i.e., the distance from the dielectric plate is set to be about 100 mm or greater, this area is also a plasma diffusion area, so that the plasma etching process can be performed sufficiently.

Desirably, the process of generating the plasma includes setting a pressure inside the processing chamber to be equal to or less than about 200 mTorr. Under this condition, the plasma etching process can be performed more properly.

More desirably, the process of performing the plasma etching process includes supplying a reactant gas containing a halogen-based gas. As a desirable embodiment, the process of performing the plasma etching process includes performing a plasma etching process on a polysilicon-based film. In this manner, re-dissociation of an etching reaction product of a halogen-based element and silicon can be suppressed efficiently.

In accordance with another aspect of the present disclosure, there is provided a plasma etching apparatus including: a processing chamber for performing therein a plasma etching process on a target substrate to be processed; a reactant gas supply unit for supplying a reactant gas for plasma etching process into the processing chamber; a holding table disposed in the processing chamber, for holding the target substrate thereon; a microwave generator for generating a microwave for plasma excitation; a dielectric plate disposed at a position facing the holding table, for introducing the microwave into the processing chamber; and a control unit for controlling a gap between the holding table and the dielectric plate to be equal to or greater than about 100 mm and a pressure inside the processing chamber to be equal to or higher than about 50 mTorr during the plasma etching process.

In accordance with this plasma etching apparatus, re-dissociation of the reaction product generated during the etching process can be suppressed, so that a micro-loading effect or a difference in sparseness and denseness of etching shapes can be suppressed and a reduction of etching selectivity can be prevented. Furthermore, under such a relatively high pressure condition, the plasma etching process can be performed readily in consideration of equipments. Thus, a control of etching shapes can be readily and properly carried out.

In accordance with this plasma etching method and plasma etching apparatus, since plasma is generated by using the microwave as a plasma source, a possibility of presence of high-energy electrons is low and an electron temperature is low. Further, as a distance from an area directly under the dielectric plate, i.e., a plasma generation area is increased, plasma becomes uniform and the electron density of plasma is decreased and the amount of plasma having a high electron temperature is reduced. Furthermore, as the pressure inside the processing chamber is increased to above a preset pressure, the electron density of plasma is decreased and the amount of the plasma having a high electron temperature is reduced. Here, by setting the gap between the holding table and the dielectric plate to be equal to or greater than about 100 mm and the pressure inside the processing chamber to be equal to or higher than about 50 mTorr, the plasma etching process can be performed under a condition that plasma necessary for the plasma etching process is in a uniform state and the amount of plasma having a high electron temperature is reduced. Therefore, re-dissociation of a reaction product generated during the etching process can be suppressed, so that a micro-loading effect or a difference in sparseness and denseness of etching shapes can be suppressed and a reduction of etching selectivity can be prevented. Furthermore, under such a relatively high pressure condition, the plasma etching process can be performed readily in consideration of equipments. Thus, a control of etching shapes can be readily and properly carried out during the plasma etching process.

### BRIEF DESCRIPTION OF THE DRAWINGS

The disclosure may best be understood by reference to the following description taken in conjunction with the following figures:

FIG. 1 is a schematic cross sectional view illustrating major parts of a plasma processing apparatus in accordance with an embodiment of the present disclosure;

FIG. 2 is a graph showing relationships between electron energy and an electron energy distribution function of microwave plasma and ICP;

FIG. 3 is a graph showing a relationship between a distance from a dielectric plate and an electron density of plasma when the distance is set to be less than about 100 mm;

FIG. 4 is a graph showing a relationship between the distance from the dielectric plate and an electron density of plasma when the distance is set to be equal to or greater than about 100 mm;

FIG. 5 is a graph showing a relationship between a pressure inside a processing chamber and an electron density of plasma;

FIG. 6 is a graph showing a relationship between a pressure inside the processing chamber and a maximum electron temperature of plasma;

FIG. 7 is a diagram showing a plasma distribution when a gap is set to be about 105 mm under a certain condition;

FIG. 8 is a diagram showing a plasma distribution when a gap is set to be about 85 mm under a certain condition;

FIG. 9 is a diagram showing a plasma distribution when a gap is set to be about 105 mm under a certain condition;

FIG. 10 is a diagram showing a plasma distribution when a gap is set to be about 85 mm under a certain condition;

FIG. 11 is an electron micrograph showing a part of a semiconductor substrate when an etching process is performed by CCP;

FIG. 12 is an enlarged view of a protrusion portion shown in FIG. 11;

FIG. 13 is an electron micrograph showing a part of a semiconductor substrate when a plasma etching process in accordance with an embodiment of the present disclosure is performed;

FIG. 14 is an enlarged view of a protrusion portion shown in FIG. 13;

FIG. 15 is a schematic diagram of FIG. 11;

FIG. 16 is a schematic diagram of FIG. 12;

FIG. 17 is a schematic diagram of FIG. 13;

FIG. 18 is a schematic diagram of FIG. 14;

FIG. 19 is an electron micrograph showing a part of a conventional semiconductor substrate having a three-dimensional structure;

FIG. 20 is an electron micrograph showing a part of a semiconductor substrate having a three-dimensional structure when a plasma etching method in accordance with an embodiment of the present disclosure is performed;

FIG. 21 is an electron micrograph showing a part of a semiconductor substrate when an etching process is performed while setting a distance to be about 135 mm;

FIG. 22 is an electron micrograph showing a part of a semiconductor substrate when an etching process is performed while setting a distance to be about 275 mm; and

FIG. 23 shows schematic diagrams illustrating a conventional process of forming a sacrificial oxide film on a silicon layer damaged by plasma in a plasma process using ICP or the like, and then etching the sacrificial oxide film to form a silicon layer containing a small amount of plasma damaged portion.

### DETAILED DESCRIPTION OF THE INVENTION

Hereinafter, embodiments of the present disclosure will be described in detail with reference to the accompanying drawings.

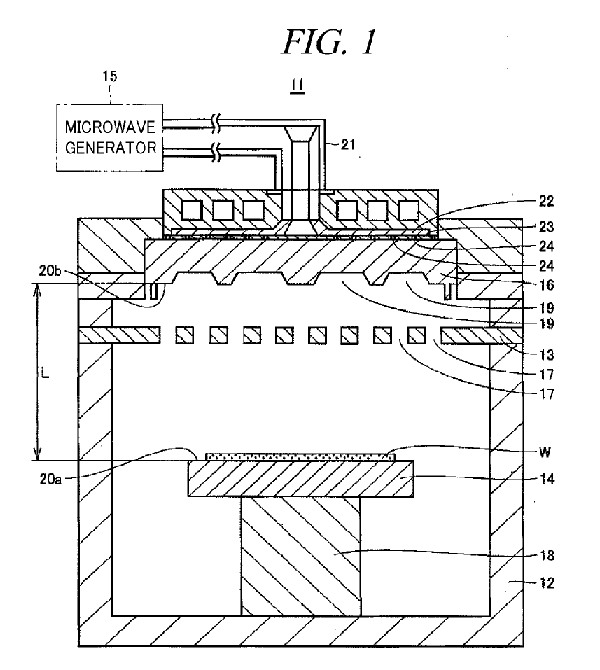

FIG. 1 is a schematic cross sectional view showing major parts of a plasma etching apparatus in accordance with an embodiment of the present disclosure. In each drawing described below, an upper side of the drawing will be defined as an upward direction.

Referring to FIG. 1, a plasma etching apparatus 11 includes: a processing chamber 12 for performing therein a plasma etching process on a semiconductor substrate W as a target object to be processed; a gas shower head 13 which has a plurality of openings 17 and serves as a reactant gas supply unit for supplying a reactant gas for use in the plasma etching process into the processing chamber 12; a holding table 14 of a circular plate shape disposed on a support 18 extending upward from a bottom surface of the processing chamber 12, for holding the semiconductor substrate W thereon; a microwave generator 15 shown by a dashed dotted line in FIG. 1, for generating a microwave for plasma excitation; a dielectric plate 16 disposed at a position facing the holding table 14, for introducing the microwave generated by the microwave generator 15 into the processing chamber 12; and a control unit (not shown) for controlling the entire plasma etching apparatus 11. The control unit controls processing conditions such as a gas flow rate in the gas shower head 13, an internal pressure of the processing chamber 12, and the like, for performing the plasma etching process on the semiconductor substrate W. A gaseous mixture containing, for example, a halogen-based gas such as HBr, Cl₂, CF₄, C₄F₈, C₄F₆, C₆F₆, or the like may be used as the reactant gas for the plasma etching process. Further, O₂, Ar, or the like may be added to the halogen-based gas at a certain mixture ratio.

A top portion of the processing chamber 12 is opened, and the processing chamber 12 is configured to be hermetically sealed by a sealing member (not shown) and the dielectric plate 16 disposed at the top portion of the processing chamber 12. The plasma processing apparatus 11 includes a vacuum pump (not shown), a gas exhaust pipe (not shown), and so forth, so that it is possible to set the internal pressure of the processing chamber 12 to a preset level by depressurizing the inside of the processing chamber 12.

A heater (not shown) for heating the semiconductor substrate W up to a preset temperature during the plasma etching process is installed inside the holding table 14. The microwave generator 15 includes a high frequency power supply (not shown) and so forth, and the holding table 14 is also connected with a high frequency power supply (not shown) for supplying a bias voltage thereto during the plasma etching process.

The dielectric plate 16 has a circular plate shape and is made of a dielectric material. The dielectric plate 16 is provided at its bottom portion with a plurality of annular recess portions 19 recessed in tapered shapes. Due to the presence of the recess portions 19, it is possible to efficiently generate plasma below the dielectric plate 16 by the microwave.

The plasma processing apparatus 11 also includes a waveguide 21 for introducing the microwave generated by the microwave generator 15 into the processing chamber 12; a wavelength shortening plate 22 for propagating the microwave; and a slot antenna 23 of a thin circular plate shape for introducing the microwave into the dielectric plate 16 through a plurality of slot holes 24 provided therein. The microwave generated by the microwave generator 15 is propagated to the wavelength shortening plate 22 through the waveguide 21 and then is introduced into the dielectric plate 16 via the slot holes 24 provided in the slot antenna 23. By the microwave introduced in the dielectric plate 16, an electric field is generated directly under the dielectric plate 16 and plasma ignition is performed, whereby the plasma by the microwave is generated inside the processing chamber 12.

Now, a plasma etching method of the semiconductor substrate W in accordance with an embodiment of the present disclosure, which is performed by using the plasma etching apparatus 11 configured as described above, will be explained.

First, after a distance between the holding table 14 and the dielectric plate 16 is set to be a preset value, the semiconductor substrate W as a target substrate is held on the holding table 14. Then, the inside of the processing chamber 12 is depressurized to a preset pressure. Subsequently, a microwave for plasma excitation is generated by the microwave generator 15 and then the microwave is introduced into the processing chamber 12 via the dielectric plate 16. Thereafter, the plasma is generated inside the processing chamber 12 by plasma ignition. Then, a reactant gas is supplied by the gas shower head 13, so that a plasma etching process is performed on the semiconductor substrate W.

When the plasma etching process is performed, an etching reaction product is generated. For example, when the plasma etching process is performed on, e.g., a polysilicon layer of the semiconductor substrate W by using a reactant gas containing HBr, SiBr is generated as an etching reaction product.

Now, a dissociation degree of the etching reaction product will be explained. The dissociation degree of the etching reaction product may be expressed by a formula of Te×τ×Ne×(σ×V). Here, Te is an electron temperature of the plasma, and Ne is an electron density of the plasma. Further, τ is a volume of a space above the semiconductor substrate where the reaction product stays and is constant, and (σ×V) is a mean of a cross sectional area of a molecule multiplied by an electron velocity. To reduce the dissociation degree of the etching reaction product, that is, to suppress re-dissociation of the etching reaction product, each parameter value of the above formula needs to be decreased. Further, a binding energy for Si—Si is about 2.3 eV, and a binding energy for Si—Br, which is a representative etching reaction product, is about 3.2 eV. Further, a binding energy for a Si—F bond of SiF, which is an etching reaction product generated when using a fluorine-based gas, is about 5.9 eV.

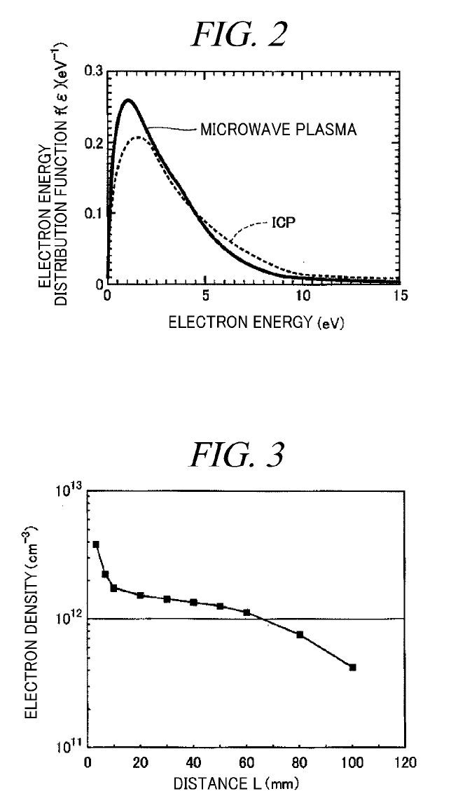

Here, a relationship between an EEDF (Electron Energy Distribution Function) and electron energy of the microwave plasma generated by the above-described plasma etching method and plasma etching apparatus will be explained. FIG. 2 is a graph showing the relationship between the EEDF and the electron energy of the microwave plasma. In FIG. 2, a horizontal axis indicates the electron energy (eV) and a vertical axis represents the EEDF f(ε) (eV⁻¹). Further, FIG. 2 also shows a relationship between an EEDF and electron energy of ICP as a comparative example. As shown in FIG. 2, in both of the ICP and the microwave plasma, their EEDFs rapidly decrease with the increase of the electron energy. Here, the microwave plasma generated by the above-stated plasma etching method and plasma etching apparatus shows a more rapid decrease of the EEDF with the increase of the electron energy, as compared to the ICP. That is, in accordance with the above-described plasma etching method and plasma etching apparatus, a possibility of presence of high-energy electrons, which may cause re-dissociation of the reaction product, becomes lower than that in case of using the ICP.

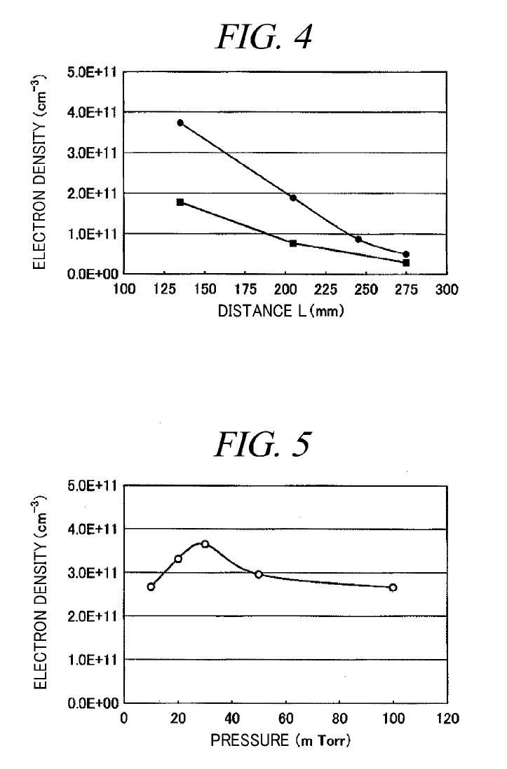

With regard to the microwave plasma generated by the above-described plasma etching method and plasma etching apparatus, a relationship between a distance from the dielectric plate 16 in the processing chamber 12 and an electron density of the plasma will be explained. FIGS. 3 and 4 are graphs showing the relationship between the electron density of the plasma and the distance from the dielectric plate 16, i.e., a gap between the dielectric plate 16 and the holding table 14. In each of FIGS. 3 and 4, a horizontal axis represents the gap between a top surface 20a of the holding table 14, on which the semiconductor substrate W is mounted and held, and a bottom surface 20b of the dielectric plate 16 indicated as a distance L (mm) from the dielectric plate 16, and a vertical axis represents the electron density (cm⁻³) of the plasma. Further, the bottom surface 20b of the dielectric plate 16 is a surface of the dielectric plate 16's flat portion on which the recess portion 19 is not provided. FIGS. 3 and 4 show results of performing etching processes under different conditions. In FIGS. 3 and 4, a black square mark indicates a case of etching a gate oxide film formed on the semiconductor substrate W, while a black circle mark indicates a case of etching a sacrificial oxide film formed by a thermal oxidation. FIG. 3 shows a case in which the distance L from the dielectric plate 16 is equal to or smaller than about 100 mm, and FIG. 4 illustrates a case in which the distance L from the dielectric plate 16 is more than about 100 mm.

Referring to FIGS. 3 and 4, in any of the two cases, the electron density of the plasma decreases with the increase of the distance L from the dielectric plate 16. Further, the electron density of the plasma is about 1.2×10¹¹ (cm⁻³) when the distance L is about 100 mm. Moreover, in the configuration of the present apparatus, an area having a distance L equal to or below about 40 mm functions as a plasma generation area whereas an area having a distance L more than about 40 mm functions as a plasma diffusion area.

Subsequently, with respect to the microwave plasma generated by the above-described plasma etching method and plasma etching apparatus, a relationship between a pressure inside the processing chamber 12 and the electron density of the plasma will be explained. FIG. 5 is a graph showing the relationship between the pressure inside the processing chamber 12 and the electron density of the plasma. In FIG. 5, a horizontal axis represents the pressure (mTorr) inside the processing chamber 12 and a vertical axis indicates the electron density (cm⁻³) of the plasma. Referring to FIG. 5, within a pressure range below about 30 mTorr, the electron density of the plasma increases with the rise of the pressure. Within a pressure range higher than about 30 mTorr, however, the electron density of the plasma decreases as the pressure increases. At a pressure of about 50 mTorr, the electron density of the plasma is about 3×10¹¹ (cm⁻³). By setting the pressure to be equal to or higher than about 50 mTorr, the electron density of the plasma can certainly have a low value.

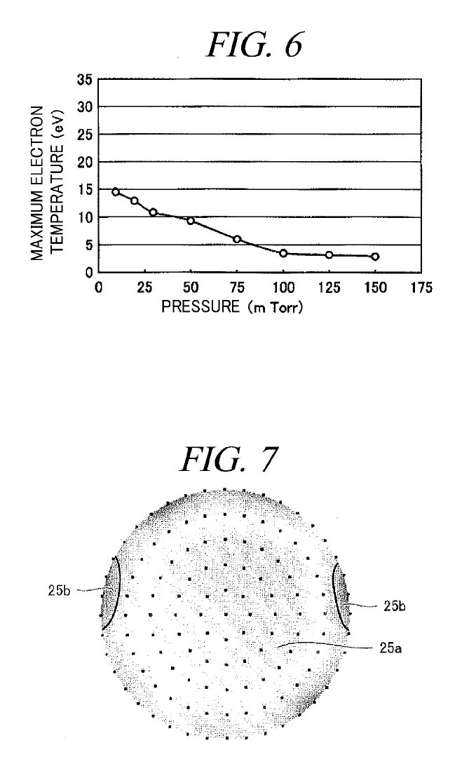

Now, with respect to the microwave plasma generated by the above-described plasma etching method and plasma etching apparatus, a relationship between a pressure inside the processing chamber 12 and a maximum electron temperature will be explained. FIG. 6 is a graph showing the relationship between the pressure inside the processing chamber 12 and the maximum electron temperature. In FIG. 6, a horizontal axis represents the pressure (mTorr) inside the processing chamber 12, and a vertical axis indicates the maximum electron temperature (eV). As can be seen from FIG. 6, the maximum electron temperature decreases with the rise of the pressure. To elaborate, the maximum electron temperature is less than about 10 eV at a pressure of about 50 mTorr, and it further decreases to less than about 5 eV at a pressure higher than about 100 mTorr. If the pressure is set to be about 200 mTorr, the maximum electron temperature can surely be less than about 5 eV.

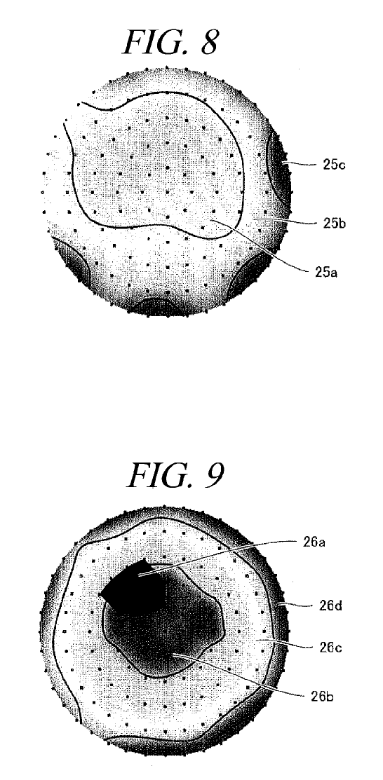

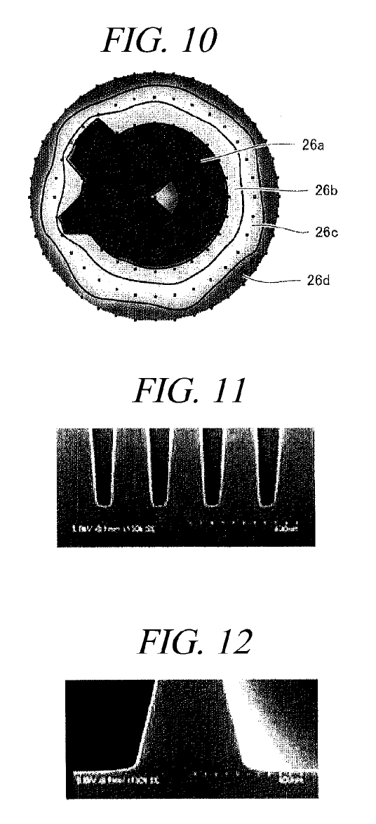

Now, with respect to the microwave plasma generated by the above-described plasma etching method and plasma etching apparatus, the gap between the holding table 14 and the dielectric plate 16 and uniformity of the plasma will be explained. FIGS. 7 to 10 illustrate plasma distributions under certain conditions. FIGS. 7 and 9 show cases in which the gap is about 105 mm, while FIGS. 8 and 10 show cases in which the gap is about 85 mm. Further, in FIGS. 7 and 8 and in FIGS. 9 and 10, other conditions except the gap are the same. Moreover, each of regions 25a to 25c and 26a to 26d of FIGS. 7 to 10 is depicted to show an area where the plasma concentration is substantially the same. The plasma concentration increases in the order of the regions 25a, 25b and 25c and in the order of the regions 26a, 26b, 26c and 26d.

Referring to FIGS. 7 and 8, a difference in the plasma concentrations is smaller when the gap is about 105 mm than a difference when the gap is about 85 mm. Further, referring to FIGS. 9 and 10, a difference in the plasma concentrations is also smaller when the gap is about 105 mm than a difference when the gap is about 85 mm. Thus, by setting the gap to be equal to or greater than about 100 mm, the plasma concentration distribution can be uniform.

Here, the gap between the holding table 14 and the dielectric plate 16 is set to be equal to or greater than about 100 mm, and the pressure inside the processing chamber 12 is set to be equal to or higher than about 50 mTorr. In this manner, the plasma etching process can be performed under a condition that plasma necessary for the plasma etching process is in a uniform state and the amount of plasma having a high electron temperature is reduced. In such a case, re-dissociation of the reaction product generated during the etching can be suppressed, so that a micro-loading effect or a difference in sparseness and denseness of etching shapes can be suppressed, and a reduction of selectivity can be prevented during the plasma etching process. Moreover, under such a relatively high pressure condition, the plasma etching process can be performed readily in consideration of equipments. Thus, a control of etching shapes can be readily and properly carried out.

In such a case, it may be possible to make the apparatus have a configuration in which the gap between the holding table 14 and the dielectric plate 16 is set to be equal to or greater than about 100 mm, or it may be possible to configure, e.g., the holding table 14 to be movable up and down and set the gap between the holding table 14 and the dielectric plate 16 to be equal to or greater than about 100 mm by adjusting a height in vertical direction of the holding table 14 in response to a control by the control unit.

Desirably, the pressure inside the processing chamber 12 is set to be about 200 mTorr or below, whereby the plasma etching process can be performed more appropriately.

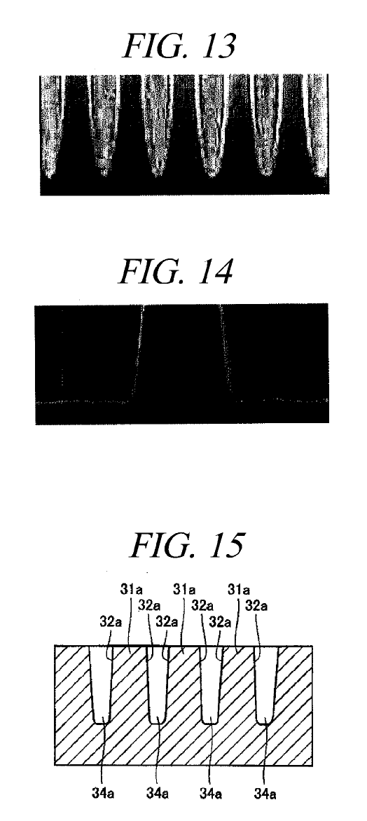

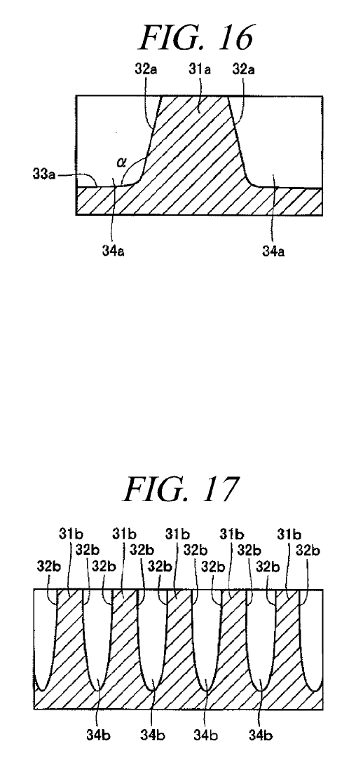

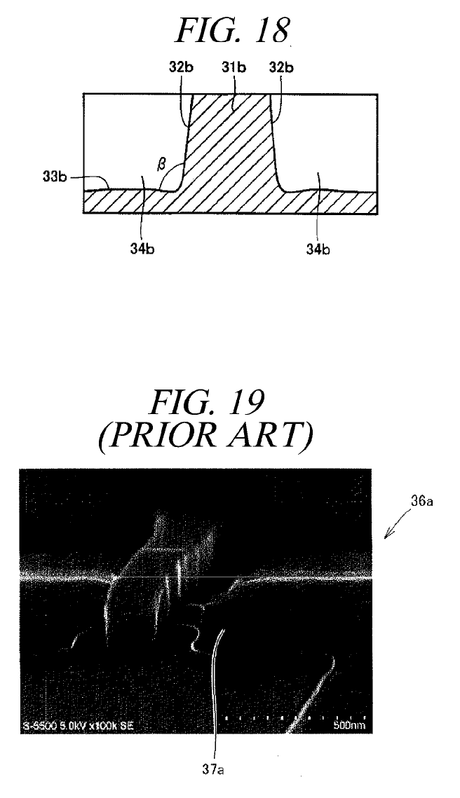

Now, there will be described a difference in shapes between a semiconductor substrate when the above-described plasma etching process is performed and a semiconductor substrate when an etching process by parallel plate type plasma (CCP: Capacitively Coupled Plasma) is performed. Each of FIGS. 11 to 14 is an electron micrograph showing a part of a semiconductor substrate when a layer having protrusion portions formed on the semiconductor substrate is etched. FIG. 11 illustrates the result of performing the etching process by the parallel plate type plasma (CCP), and FIG. 12 is an enlarged view of a protrusion portion shown in FIG. 11. FIG. 13 illustrates the result of performing the above-described plasma etching process, and FIG. 14 is an enlarged view of a protrusion portion shown in FIG. 13. Further, schematic diagrams corresponding to FIGS. 11 to 14 are provided in FIGS. 15 to 18, respectively.

Referring to FIGS. 11, 12, 15 and 16, as for the case of the parallel plate type plasma (CCP), a lot of depositions are deposited on a sidewall 32a of a protrusion portion 31a, and an angle a between a bottom surface 33a and the sidewall 32a is a large obtuse angle. Further, a recess portion 34a formed between adjacent protrusion portions 31a is not sufficiently recessed. In contrast, referring to FIGS. 13, 14, 17 and 18, when using the above-described microwave plasma, few depositions are deposited on a sidewall 32b of a protrusion portion 31b, and an angle β between a bottom surface 33b and the sidewall 32b is closer to a right angle as compared to the angle α. In addition, a recess portion 34b formed between adjacent protrusion portions 31b is sufficiently recessed. That is, as compared to a case of performing the etching process by the CCP, a micro-loading effect or a difference in sparseness and denseness of etching shapes is suppressed when the above-described plasma etching process is performed.

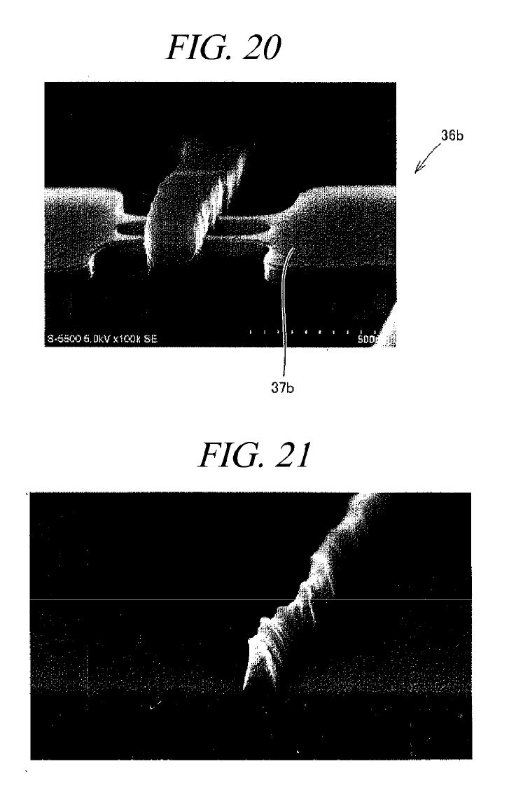

Moreover, the above-described plasma etching process is applicable to a semiconductor substrate having a three-dimensional structure. FIG. 19 is an electron micrograph showing a part of a conventional semiconductor substrate having a three-dimensional structure. FIG. 20 is an electron micrograph showing a part of a semiconductor substrate on which the above-described plasma etching process has been performed. As shown in FIGS. 19 and 20, as compared to a conventional case in which a gate oxide film 37a on a semiconductor substrate 36a is largely etched, a gate oxide film 37b on a semiconductor substrate 36b is not etched as much as the gate oxide film 37a shown in FIG. 19 in the above-described plasma etching process. Thus, a reduction of selectivity can be prevented.

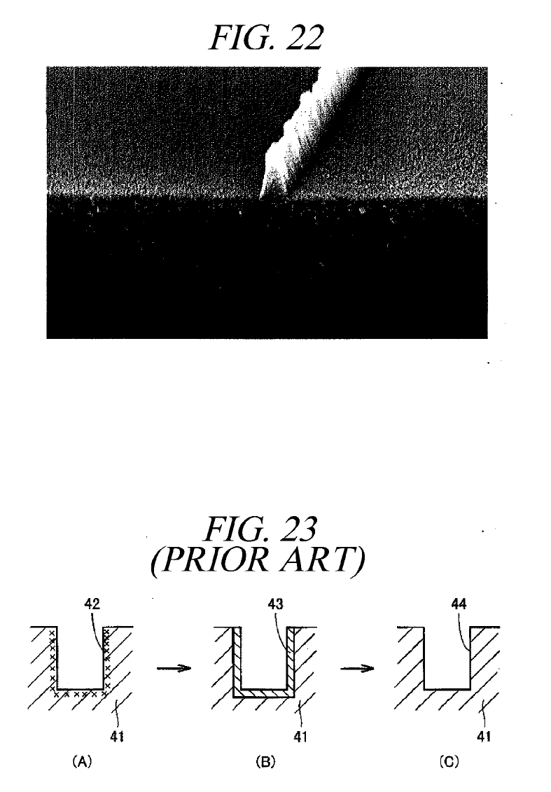

FIGS. 21 and 22 are electron micrographs showing a partial state after performing an etching process on a semiconductor substrate when altering a distance L. FIG. 21 shows a case in which the distance L is about 135 mm, and FIG. 22 shows a case in which the distance L is about 275 mm. Referring to FIGS. 21 and 22, the shape of a leading end of a protrusion portion becomes even and uniform if the etching process is performed with the distance L of about 275 mm as compared to a case with the distance L of about 135 mm.

Further, such a plasma etching process, i.e., the plasma etching process, in which the microwave plasma is used and the gap between the holding table and the dielectric plate is set to be equal to or greater than about 100 mm and the pressure inside the processing chamber is set to be equal to or more than about 50 mTorr, accompanies little plasma damage on the semiconductor substrate. Accordingly, this process is very effective when forming a silicon layer containing a small amount of plasma damaged portion as will be described below.

FIG. 23 shows schematic diagrams illustrating a conventional process of forming a sacrificial oxide film on a silicon layer damaged by plasma in a plasma process using ICP or the like, and then etching the sacrificial oxide film to form a silicon layer containing a small amount of plasma damaged portion. In FIG. 23, (A) illustrates a process in which a plasma damaged layer is formed due to the plasma etching process; (B) illustrates a process of forming the sacrificial oxide film on the plasma damaged layer; and (C) illustrates a process of removing the formed sacrificial oxide film by wet etching.

Referring to FIG. 23, conventionally, the plasma etching process by the ICP or the like is performed on a silicon layer 41, and a plasma damaged layer 42 is formed (A). Then, to remove the plasma damaged layer 42, a thermal oxidation is performed on the plasma damaged layer 42, so that a sacrificial oxide film 43 is formed. Then, by using hydrofluoric acid (HF) or the like, the formed sacrificial oxide film 43 is removed by wet etching which accompanies little damage. In this manner, the silicon layer 41 whose surface 44 contains a small amount of plasma damaged portion is formed. Since this process includes the thermal oxidation process, it is difficult to employ this process when a high-temperature process needs to be avoided. Further, since this process also includes the wet etching process, the configuration of the processing apparatus becomes complicated.

By using the plasma etching method and the plasma etching apparatus in accordance with the present disclosure, the process of forming the silicon layer containing a small amount of plasma damaged portion can be simplified.

As a first embodiment for forming a silicon layer containing a small amount of plasma damaged portion, a conventional etching process is carried out by using plasma such as ICP or the like, and then the above-described plasma etching process is performed. In this manner, after performing the above-described plasma etching process, a silicon layer containing a small amount of plasma damaged portion due to the plasma can be formed. In such a case, the plasma process is performed by using self-bias caused by a reactant gas such as CF₄ and O₂ while bias is not applied to a semiconductor substrate, so that the damage can be further reduced. In this manner, the processes (B) and (C) in FIG. 23 can be omitted.

As a second embodiment for forming a silicon layer containing a small amount of plasma damaged portion, after performing the above-described plasma etching process, the conventional thermal oxidation and wet etching are performed, so that a silicon layer containing a small amount of plasma damaged portion is formed. In such a case, since the damage of the silicon layer caused by the plasma etching process is small, the processes (B) and (C) of FIG. 23 can be shortened.

As a third embodiment for forming a silicon layer containing a small amount of plasma damaged portion, after performing a general microwave plasma process, the above-described plasma etching process is performed. Through this process, a silicon layer containing a small amount of plasma damaged portion can be formed. In such a case, the processes (B) and (C) of FIG. 23 can also be omitted.

Further, in the above-described embodiments, though the reactant gas containing the halogen-based gas is used as the reactant gas for the plasma etching process, it is not limited thereto, and a reactant gas containing no halogen-based gas can also be used.

Furthermore, in the above-described embodiments, though the case of performing the plasma etching process on the silicon layer has been described, it is not limited thereto, and the plasma etching process can be performed on other layers as well.

The above description of the present invention is provided for the purpose of illustration, and it would be understood by those skilled in the art that various changes and modifications may be made without changing technical conception and essential features of the present invention. Thus, it is clear that the above-described embodiments are illustrative in all aspects and do not limit the present invention.

The scope of the present invention is defined by the following claims rather than by the detailed description of the embodiment. It shall be understood that all modifications and embodiments conceived from the meaning and scope of the claims and their equivalents are included in the scope of the present invention.

What is claimed is:

1. A plasma etching method for performing a plasma etching process on a target substrate to be processed, the method comprising:
holding the target substrate on a holding table installed in a processing chamber;
generating a microwave for plasma excitation;
generating plasma in the processing chamber by setting a gap between the holding table and a dielectric plate, which is disposed at a position facing the holding table to generate the plasma in the processing chamber by introducing the microwave into the processing chamber, to be equal to or greater than about 100 mm and setting a pressure inside the processing chamber to be equal to or higher than about 50 mTorr, and introducing the microwave into the processing chamber via the dielectric plate; and
performing a plasma etching process on the target substrate by the plasma generated by supplying a reactant gas for plasma etching process into the processing chamber.

2. The plasma etching method of claim 1, wherein the process of generating the plasma includes:
setting a pressure inside the processing chamber to be equal to or less than about 200 mTorr.

3. The plasma etching method of claim 1, wherein the process of performing the plasma etching process includes:
supplying a reactant gas containing a halogen-based gas.

4. The plasma etching method of claim 1, wherein the process of performing the plasma etching process includes:
performing a plasma etching process on a polysilicon-based film.

5. A plasma etching apparatus comprising:
a processing chamber for performing therein a plasma etching process on a target substrate to be processed;
a reactant gas supply unit for supplying a reactant gas for plasma etching process into the processing chamber;
a holding table disposed in the processing chamber, for holding the target substrate thereon;
a microwave generator for generating a microwave for plasma excitation;
a dielectric plate disposed at a position facing the holding table, for introducing the microwave into the processing chamber; and
a control unit for controlling a gap between the holding table and the dielectric plate to be equal to or greater than about 100 mm and a pressure inside the processing chamber to be equal to or higher than about 50 mTorr during the plasma etching process.
